(19) United States
(12) Patent Application Publication
(10) Pub. No.: US 2012/0325284 A1
(43) Pub. Date: Dec. 27, 2012

(54) THIN-FILM SILICON TANDEM SOLAR CELL AND METHOD FOR MANUFACTURING THE SAME

(75) Inventors: Tobias Roschek, Alt St. Johann (CH); Hanno Goldbach, Sevelen (CH)

(73) Assignee: OERLIKON SOLAR AG, TRUEBBACH, Truebbach (CH)

(21) Appl. No.: 13/516,261

(22) PCT Filed: Oct. 28, 2010
(86) PCT No.: PCT/EP2010/066295

§ 371 Date: Jun. 15, 2012

Related U.S. Application Data
(60) Provisional application No. 61/289,054, filed on Dec. 22, 2009.

(51) Int. Cl. H01L 31/042; H01L 31/076; H01L 31/20

(52) U.S. Cl. 136/244; 438/96; 136/255; 257/E31.062

(57) ABSTRACT

The photovoltaic cell comprises, deposited on a transparent substrate in the following order: a first conductive oxide layer; a first p-i-n junction; a second p-i-n junction; a second conductive oxide layer, wherein said first conductive oxide layer is substantially transparent and comprises a low-pressure chemical vapor deposited ZnO layer; and said second conductive oxide layer comprises an at least partially transparent low-pressure chemical vapor deposited ZnO layer; and wherein said first p-i-n junction comprises in the following order: a layer of p-doped a-Si:H deposited using PECVD and having at its end region facing toward said second p-i-n junction a higher band gap than at its end region facing toward said first conductive oxide layer; a buffer layer of a-Si:H deposited using PECVD without voluntary addition of a dopant; a layer of substantially intrinsic a-Si:H deposited using PECVD; a first layer of n-doped a-Si:H deposited using PECVD; and a layer of n-doped μc-Si:H deposited using PECVD; and wherein said second p-i-n junction comprises in the following order a layer of p-doped μc-Si:H deposited using PECVD; a layer of substantially intrinsic μc-Si:H deposited using PECVD; and a second layer of n-doped a-Si:H deposited using PECVD. The photovoltaic converter panel comprises at least one such photovoltaic cell.

### TECHNICAL FIELD

The invention relates to photovoltaic cells, in particular tandem cells, and photovoltaic converter panels and to methods for manufacturing the same. It relates to methods and devices according to the opening clauses of the claims.

### ABBREVIATIONS AND DEFINITIONS FOR THE PRESENT PATENT APPLICATION

PECVD:

PECVD stands for plasma-enhanced chemical vapor deposition.

LPCVD:

LPCVD stands for low-pressure chemical vapor deposition.

μc-Si:H/Microcrystalline:

μc-Si:H designates microcrystalline hydrogenated silicon. This microcrystalline material has at least 10 vol. % crystallinity (crystallites embedded in a more or less porous matrix of hydrogenated amorphous silicon, a-Si:H). Microcrystalline grains have a diameter perpendicular to their length extension of between 5 nm and 100 nm.

a-Si:H/Amorphous:
a-Si:H designates amorphous hydrogenated silicon. This amorphous material has less than 10 vol. % crystallinity, i.e less than 10 vol. % of crystalline grains having a diameter perpendicular to their length extension of between 5 nm and 100 nm.

Substantially Intrinsic:

A layer or material referred to as “intrinsic” is semiconducting with the Fermi-level located at least substantially in the middle between its valence band and the conduction band, i.e. midgap; no doping is applied, neither voluntary doping nor involuntary doping. Layers or materials referred to as “substantially intrinsic” comprise “intrinsic” layers and materials, respectively, as defined above, and, in addition, voluntarily and/or involuntarily compensated semiconducting layers or materials, i.e. layers and materials in which the Fermi-level is at least approximately midgap due to a voluntary and/or an involuntary doping.

Thickness:

When referring to a thickness of a layer or layer stack, we refer to an averaged thickess of said layer or layer stack perpendicular to its lateral extension, averaged over its lateral extension.

### BACKGROUND OF THE INVENTION

Photovoltaic solar energy conversion offers the perspective to provide an environmentally-friendly means to generate electricity. However, at the present state, electric energy provided by photovoltaic energy conversion units such as photovoltaic cells and corresponding photovoltaic converter panels is still significantly more expensive than electricity provided by conventional power stations. Therefore, the development of more cost-effective manufacturing processes for photovoltaic energy conversion units attracts much attention already for several years, as does the development of more efficient photovoltaic energy conversion units.

Among different approaches of manufacturing low-cost solar cells, thin-film silicon solar cells combine several advantageous aspects: Firstly, thin-film silicon photovoltaic cells can be manufactured based on thin-film deposition techniques such as plasma-enhanced chemical vapor deposition (PECVD) and thus may profit from synergies with well-known deposition techniques, thus allowing to reduce manufacturing costs by using experiences achieved in the past, e.g., in other technical fields employing thin-film deposition, such as in the display manufacturing sector. Secondly, thin-film silicon photovoltaic cells can achieve high conversion efficiencies (also referred to as “quantum efficiency” or simply “efficiency”), striving for 10% and beyond. Thirdly, the main raw materials for the manufacturing of thin-film silicon based photovoltaic cells are abundant and non-toxic.

Amongst various approaches for manufacturing thin-film silicon photovoltaic cells and photovoltaic converter panels, in particular the concept of stacking two p-i-n or n-i-p junctions, also known as tandem concept (“tandem cells”), or stacking even more p-i-n or n-i-p junctions, offers the perspective of achieving conversion efficiencies exceeding 10% due to the better exploitation of the (typically solar) irradiation spectrum when compared to single cells with only one p-i-n or n-i-p junction in a row.

A thin-film photovoltaic cell structure includes a first electrode, one or more stacked p-i-n or n-i-p junctions and a second electrode. The electrodes are used for tapping off electric current from the cell structure.

FIG. 1 shows a basic simple photovoltaic single cell 40. It comprises a transparent substrate 41, e.g., of glass, with a layer of a transparent conductive oxide (TCO) 42 deposited thereon acting as one of the electrodes. In the art, this layer is also referred to as “Front Contact” (FC). Then, the active layers follow. The junction 43 in the present example consists of a p-i-n junction of layers 44, 45 and 46. Layer 44 adjacent to the TCO layer 42 is positively doped (p-doped); the subsequent layer 45 is substantially intrinsic, and the final layer 46 is negatively doped (n-doped). In an alternative embodiment, the layer sequence p-i-n as described is inverted to n-i-p. In that case, layer 44 is n-doped and layer 46 is p-doped. Finally, the cell 40 comprises a rear contact layer 47 also referred to as “Back Contact” (BC), which may be made of zinc oxide, tin oxide or Indium Tin Oxide (ITO) and which customarily is provided with a reflective layer 48. Alternatively, the back contact may be realized by a metallic material which may combine the physical properties of back reflector 48 and back contact 47. In FIG. 1, the arrows indicate the impinging light for illustrative purposes.

For tandem photovoltaic cell structures, it is known in the art to combine a p-i-n or n-i-p junction having a substantially intrinsic layer of amorphous hydrogenated silicon (a-Si:H) being particularly sensitive in a shorter wavelength spectrum with a p-i-n or n-i-p junction having a substantially intrinsic layer of microcrystalline hydrogenated silicon (μc-Si:H) for exploiting a relatively longer wavelengths spectrum of solar spectrum.

For illustrative purposes, FIG. 2 shows a photovoltaic tandem cell structure. Like in the cell 40 of FIG. 1, the cell 50 of FIG. 2 comprises a substrate 41 and, as a first electrode (Front Electrode, FC), a layer of transparent conductive oxide TCO 44, as was addressed in conjunction with FIG. 1. The cell 50 further comprises the junction 43, e.g., a p-i-n junction of hydrogenated silicon comprising three layers 44, 45 and 46 like the corresponding layers in the embodiment of FIG. 1. There is further provided a rear contact layer 47 as a second electrode and a reflective layer 48. The properties and requirements of the cell 50 of FIG. 2 as described so far are the same as described in conjunction with FIG. 1.

The cell 50 further comprises a second junction 51, e.g., another p-i-n junction of hydrogenated silicon. This junction comprises three layers 52, 53, 54 which are positively doped and substantially intrinsic and negatively doped, respectively. The p-i-n junction 51 may be located between front contact layer 42 and the p-i-n junction 43, as shown in FIG. 2. But alternatively, the two junctions 43 and 51 may be inverted with respect to their order, resulting in the following order: 42, 43, 51, 47. Again for illustrative purposes, the arrows indicate impinging light.

Considered from the direction of incident light, it is common to refer to the “top cell” which is closer to the incident light, formed in FIG. 2 by the p-i-n junction 51, and the “bottom cell”, formed in FIG. 2 by the p-i-n junction 43. In such a tandem cell structure, customarily both, junctions 43 and 51, have a substantially intrinsic layer of amorphous hydrogenated silicon (a-Si:H), or junction 51 is has a substantially intrinsic layer of amorphous hydrogenated silicon (a-Si:H), while junction 43 has a substantially intrinsic layer of microcrystalline hydrogenated silicon (μc-Si:H).

Tuning and refining the structure of such photovoltaic cells, in particular tandem cells, and their manufacturing process for achieving an increased efficiency (generated electric power per incident light power) and making them cost-efficiently manufacturable is an important task in the industry. Furthermore, it is important to tackle these tasks for large-scale industrial mass production, more particularly for photovoltaic converter panels of at least 2500 cm² surface extent; note that results obtained for small-scale laboratory samples, e.g., of a couple of cm², cannot be readily transferred to large-scale industrial mass production.

### SUMMARY OF THE INVENTION

Therefore, one object of the invention is to create photovoltaic cells and photovoltaic converter panels, respectively, which have a particularly high efficiency. In addition, the respective method for manufacturing photovoltaic cells or photovoltaic converter panels shall be provided.

Another object of the invention is to provide photovoltaic cells and photovoltaic converter panels, respectively, which are particularly efficiently manufacturable. In addition, the respective method for manufacturing photovoltaic cells or photovoltaic converter panels shall be provided.

Another object of the invention is to combine the before-mentioned objects.

Another object of the invention is to reach one or more of the before-mentioned objects for large-scale industrial mass production, more particularly for photovoltaic converter panels of at least 2500 cm² surface extent.

Another object of the invention is to provide an increased process stability in manufacturing photovoltaic cells.

Another object of the invention is to provide, in the manufacture of photovoltaic cells, an unprecedented control of the deposition of layers of a photovoltaic cell and in particular to provide an unprecedented control of their composition.

At least one of these objects is at least partially achieved by devices and methods according to the patent claims.

The photovoltaic cell comprises, deposited on a transparent substrate in the following order, a first conductive oxide layer;
a first p-i-n junction;
a second p-i-n junction;
a second conductive oxide layer;
   wherein
said first conductive oxide layer is substantially transparent and comprises or substantially is a low-pressure chemical vapor deposited ZnO (zinc oxide) layer; and
said second conductive oxide layer comprises or substantially is an at least partially transparent low-pressure chemical vapor deposited ZnO layer; and
   wherein said first p-i-n junction comprises in the following order
a layer of p-doped a-Si:H deposited using PECVD and having at its end region facing toward said second p-i-n junction a higher band gap than at its end region facing toward said first conductive oxide layer;
a buffer layer of a-Si:H deposited using PECVD without voluntary addition of a dopant;
a layer of substantially intrinsic a-Si:H deposited using PECVD;
a first layer of n-doped a-Si:H deposited using PECVD; and
a layer of n-doped μc-Si:H deposited using PECVD; and
   wherein said second p-i-n junction comprises in the following order
a layer of p-doped μc-Si:H deposited using PECVD;
a layer of substantially intrinsic μc-Si:H deposited using PECVD; and
a second layer of n-doped a-Si:H deposited using PECVD.

Through this, a very high efficiency of the photovoltaic cell can be achieved. And the cells and panels, respectively, are very well manufacturable and can be manufactured within a relatively short time.

The provision of said layer of n-doped μc-Si:H strongly facilitates a high-quality growth the said layer of p-doped μc-Si:H which finally contributes to an overall increased cell efficiency and an overall low deposition time.

In one embodiment, the photovoltaic cell comprises said substrate; in particular wherein said substrate is a glass substrate, more particularly a white-glass substrate.

In one embodiment which may be combined with the before-addressed embodiment, for a thickness d_{TCO} of said first conductive oxide layer applies 1 μm≦d_{TCO}≦4 μm, more particularly 1.3 μm≦d_{TCO}≦3 μm, and wherein for said thickness d_{TCO} and for a thickness dᵢ of said layer of substantially intrinsic μc-Si:H applies

1.25≦(d_{TCO}/μm)·(dᵢ/μm−0.4)≦2, more particularly 1.35≦(d_{TCO}/μm)*(dᵢ/μm−0.4)≦1.85. Even more particularly, d_{TCO} is at least 1.4 μm and at most 1.7. Also even more particularly, it applies 1.45≦(d_{TCO}/μm)·(dᵢ/μm−0.4)≦1.7, and even more specifically (d_{TCO}/μm)·(dᵢ/μm−0.4)=1.58±0.7.

In one embodiment which may be combined with one or more of the before-addressed embodiments, said first conductive oxide layer is n-doped, in particular by boron, more particularly by means of diborane.

In one embodiment which may be combined with one or more of the before-addressed embodiments, said first conductive oxide layer is optimized for a high electrical conductivity (perpendicularly to the layer extension), for a high transmission (of light through the layer) and for a strong scattering. Note that the electrical conductivity of the conductive oxide layers can be adjusted by suitably adjusting the amount of doping applied.

Note that strong scattering of light by said first conductive oxide layer results in a longer path of light within the photovoltaic cell (more light travelling in a direction forming a relatively large angle with the normal of the layers) and, more importantly within said layer of substantially intrinsic μc-Si:H. Accordingly, only a relatively small thickness of said layer of substantially intrinsic μc-Si:H is needed, which leads to a relatively low deposition time while still having a high efficiency.

Note that the first conductive oxide layer as described herein causes a high degree of scattering.

In one embodiment which may be combined with one or more of the before-addressed embodiments, the electrical conductivity perpendicularly to the layer extension of said first conductive oxide layer is smaller than the electrical conductivity perpendicularly to the layer extension of said second conductive oxide layer, in particular wherein the ratio of said electrical conductivities is between 2:3 and 1:2.

In one embodiment which may be combined with one or more of the before-addressed embodiments, said first conductive oxide layer is deposited at a process temperature, i.e. the temperature of said transparent substrate during said low-pressure chemical vapor deposition (LPCVD) process, of below 200° C., in particular of 160° C.±15° C.

In one embodiment which may be combined with one or more of the before-addressed embodiments, said first conductive oxide layer is deposited at a process temperature, i.e. the temperature of said transparent substrate during said low-pressure chemical vapor deposition (LPCVD) process, of below 200° C., in particular of 160° C.±15° C.

In one embodiment which may be combined with one or more of the before-addressed embodiments, said bandgap of said layer of p-doped a-Si:H at said end region facing toward said second p-i-n junction is higher than said bandgap of said layer of p-doped a-Si:H at said end region facing toward said first conductive oxide layer by at least 0.15 eV, more particularly by at least 0.2 eV and at most 0.5 eV.

In one embodiment which may be combined with one or more of the before-addressed embodiments, said layer of p-doped a-Si:H has a thickness of at least 8 nm and at most 20 nm, more particularly of at least 9 nm and at most 17 nm.

In one embodiment which may be combined with one or more of the before-addressed embodiments, the said layer of p-doped a-Si:H comprises or substantially consists of
a first layer of p-doped a-Si:H deposited using PECVD; and
a second layer of p-doped a-Si:H deposited using PECVD and having a higher band gap than said first layer of p-doped a-Si:H.

In one embodiment with said first and second layers of p-doped a-Si:H, said first and said second layers of p-doped a-Si:H have a substantially constant bandgap each.

In one embodiment with said first and second layers of p-doped a-Si:H which may be combined with the before-addressed embodiment, the bandgap of said first layer of p-doped a-Si:H amounts to 1.7 V±0.1 V, and the bandgap of said second layer of p-doped a-Si:H amounts to 2.0 V±0.1 V.

In one embodiment which may be combined with one or more of the before-addressed embodiments with said first and second layers of p-doped a-Si:H, the bandgap of said second layer of p-doped a-Si:H is higher than the bandgap of said first layer of p-doped a-Si:H by 0.3 V±0.1 V.

In one embodiment which may be combined with one or more of the before-addressed embodiments with said first and second layers of p-doped a-Si:H, said first layer of p-doped a-Si:H is deposited at a growth rate of 0.36 nm/s±0.4 nm/s.

In one embodiment which may be combined with one or more of the before-addressed embodiments with said first and second layers of p-doped a-Si:H, said second layer of p-doped a-Si:H is deposited at a growth rate of 0.22 nm/s±0.4 nm/s.

In one embodiment which may be combined with one or more of the before-addressed embodiments with said first and second layers of p-doped a-Si:H, a ratio of growth rates of said first layer of p-doped a-Si:H and said second layer of p-doped a-Si:H, respectively, is at least 1.2 and at most 1.9.

In one embodiment which may be combined with one or more of the before-addressed embodiments with said first and second layers of p-doped a-Si:H, a thickness of said first layer of p-doped a-Si:H is at most 10 nm, in particular at most 7 nm, more particularly between 1 nm and 6 nm, and a thickness of said second layer of p-doped a-Si:H is at least 5 nm and at most 16 n, more particularly between 7 nm and 13 nm, and said thickness of said second layer of p-doped a-Si:H is larger than said thickness of said first layer of p-doped a-Si:H.

It will typically be preferred to provide that said first layer of p-doped a-Si:H is as thin as possible, so as to have a very low light absorption in this layer, but at the same time thick enough to provide a sufficiently good electrical conductivity.

Note that instead of two layers of substantially constant bandgap each, it is also possible to vary the bandgap throughout said layer of p-doped a-Si:H in a continuous or quasi-continuous way. Variations in the band gap (step-wise or continuous) can be accomplished, e.g., by correspondingly varying a concentration of a gas such as CH₄ during deposition of said layer of p-doped a-Si:H.

In one embodiment which may be combined with one or more of the before-addressed embodiments, the photovoltaic cell comprises in the before-described sequence of layers immediately before said layer of p-doped μc-Si:H a first oxide layer having a thickness of less than 2.5 nm, in particular less than 2 nm, more particularly between 0.1 nm and 1.5 nm. Said thickness will usually be more than 0.4 nm and typically between 0.5 nm and 1 nm.

The provision of such a first oxide layer results in a significantly increased process stability as well as to a significantly increased reproducibility in the manufacture of the photovoltaic cells and panels, respectively.

In one embodiment which may be combined with the before-addressed embodiment, said first oxide layer is substantially formed by oxidized n-doped μc-Si:H, in particular this can be accomplished by oxidizing the underlying layer, i.e. said layer of n-doped μc-Si:H. But it is alternatively or additionally possible to deposit said first oxide layer onto said layer of n-doped μc-Si:H.

In one embodiment which may be combined with any of the before-addressed embodiments with said first oxide layer, a thickness of said layer is chosen so low that the layer does not influence optical properties of the photovoltaic cell, in particular, the thickness of the layer is chosen so low that the layer has no reflectivity or at least no relevant reflectivity.

In one embodiment which may be combined with any of the before-addressed embodiments with said first oxide layer, this layer is formed by exposing said layer of n-doped μc-Si:H to a gas atmosphere consisting of CO₂ and PH₃, more particularly to a corresponding plasma-excited gas atmosphere containing oxygen radicals, in particular wherein a gas mixing ratio of phosphine to CO₂ is between 1:1000 and 1:1, more particularly between 1:100 and 1:10).

It is possible to use other oxygen-containing gases for the addressed plasma for forming said first oxide layer. It is even thinkable that the gas atmosphere used for forming first oxide layer is not plasma-excited; in other words, generally spoken, said first oxide layer can be formed by exposing said layer of n-doped μc-Si:H to an oxygen-containing gas atmosphere.

In one embodiment which may be combined with one or more of the before-addressed embodiments, the photovoltaic cell comprises in the before-described sequence of layers immediately before said second conductive oxide layer a second oxide layer having a thickness of less than 2.5 nm, in particular less than 2 nm, more particularly between 0.1 nm and 1.5 nm. Typically, said thickness is between 0.5 nm and 1 nm.; usually at least 0.4 nm.

The provision of such a second oxide layer results in a significantly increased process stability as well as to a significantly increased reproducibility in the manufacture of the photovoltaic cell.

In one embodiment which may be combined with the before-addressed embodiment, said second oxide layer is substantially formed by oxidized a-Si:H, in particular this can be accomplished by oxidizing the underlying layer, i.e. said a second layer of n-doped a-Si:H. But it is alternatively or additionally possible to deposit said second oxide layer onto said second layer of n-doped a-Si:H.

In one embodiment which may be combined with any of the before-addressed embodiments with said second oxide layer, a thickness of said layer is chosen so low that the layer does not influence optical properties of the photovoltaic cell, in particular, the thickness of the layer is chosen so low that the layer has no reflectivity or at least no relevant reflectivity.

In one embodiment which may be combined with any of the before-addressed embodiments with said second oxide layer, this layer is formed by exposing said second layer of n-doped a-Si:H to a gas atmosphere substantially consisting of CO₂. Optionally, it is possible to use a gas atmosphere substantially consisting of CO₂ and PH₃, in particular wherein a gas mixing ratio phosphine to CO₂ is between 1:1000 and 1:1, more particularly between 1:100 and 1:10).

Like in the case of said first oxide layer (see above), it is, generally spoken, possible to form said second oxide layer by exposing said second layer of n-doped a-Si:H to an oxygen-containing gas atmosphere.

In one embodiment which may be combined with one or more of the before-addressed embodiments, the photovoltaic cell comprises in the before-described sequence of layers immediately before said layer of n-doped μc-Si:H a third oxide layer having a thickness of less than 2.5 nm, in particular less than 2 nm, more particularly between 0.1 nm and 1.5 nm.

The provision of such a third oxide layer results in a significantly increased process stability as well as to a significantly increased reproducibility in the manufacture of the photovoltaic cell.

In one embodiment which may be combined with the before-addressed embodiment, said third oxide layer is substantially formed by oxidized a-Si:H; in particular this can be accomplished by oxidizing the underlying layer, e.g., said first layer of n-doped a-Si:H. But it is alternatively or additionally possible to deposit said third oxide layer onto said first layer of n-doped a-Si:H.

In one embodiment which may be combined with any of the before-addressed embodiments with said third oxide layer, a thickness of said layer is chosen so low that the layer does not influence optical properties of the photovoltaic cell, in particular, the thickness of the layer is chosen so low that the layer has no reflectivity or at least no relevant reflectivity.

In one embodiment which may be combined with any of the before-addressed embodiments with said third oxide layer, this layer is formed by exposing said first layer of n-doped a-Si:H to a gas atmosphere substantially consisting of CO₂. Optionally, it is possible to use a gas atmosphere substantially consisting of CO₂ and PH₃, in particular wherein a gas mixing ratio phosphine to CO₂ is between 1:1000 and 1:1, more particularly between 1:100 and 1:10).

Like in the case of said first oxide layer, it is, generally spoken, possible to form said third oxide layer by exposing said first layer of n-doped a-Si:H to an oxygen-containing gas atmosphere.

In one embodiment which may be combined with one or more of the before-addressed embodiments, said buffer layer has a thickness of at least 2 nm and at most 15 nm, more particularly of at least 5 nm and at most 12 nm, even more particularly of at least 8.5 nm and at most 10.7 nm.

In one embodiment which may be combined with one or more of the before-addressed embodiments, said buffer layer is deposited using PECVD at a growth rate smaller than a growth rate of the deposition of said layer of p-doped a-Si:H, and in particular is deposited using PECVD at a growth rate of at most half of a growth rate of the deposition of said layer of p-doped a-Si:H. Even more particularly, it is deposited using PECVD at a growth rate of at most a third of a growth rate of the deposition of said layer of p-doped a-Si:H. Therein, if the growth rate of said layer of p-doped a-Si:H is not approximately constant, we refer to an averaged growth rate during the deposition of said layer of p-doped a-Si:H. In as far as said layer of p-doped a-Si:H comprises the before-addressed first and second layers of p-doped a-Si:H with different bandgaps, said growth rate for depositing said buffer layer typically is smaller than a growth rate for depositing said first layer of p-doped a-Si:H and smaller than a growth rate for depositing said second layer of p-doped a-Si:H.

Due to its low growth rate, said buffer layer is capable of very efficiently trapping contaminants present in the deposition chamber, which provides the possibility to have particularly precise control of the composition and freedom of contaminants of the subsequently deposited layer or layers. More particularly, a purpose of said buffer layer is to absorb residual dopants possibly present in the atmosphere in the deposition chamber.

In one embodiment, which may be combined with one or more of the before-addressed embodiments with the buffer layer, no dopant is added to the deposition gas during the deposition of the buffer layer.

In one embodiment which may be combined with one or more of the before-addressed embodiments, a thickness dᵢ of said layer of substantially intrinsic μc-Si:H is at least 0.8 μm and at most 2 μm, more particularly at least 1 μm and at most 1.6 μm, even more particularly 1.45 μm±0.1 μm.

A low thickness of said layer of substantially intrinsic μc-Si:H is desirable, since it strongly contributes to a low overall deposition time. An important reason why this low thickness is sufficient for still maintaining a high overall efficiency is the provision of the above-addressed first conductive oxide layer having the above-described properties. A further reason why this low thickness is sufficient for still maintaining a high overall efficiency is the provision of the above-addressed second conductive oxide layer having the above- and below-described properties.

In one embodiment which may be combined with one or more of the before-addressed embodiments, a thickness dᵢ of said layer of substantially intrinsic μc-Si:H is at least 4 times and at most 8 times as large as a thickness of said layer of substantially intrinsic a-Si:H. This turns out to very well balance the currents of the two intrinsic layers, thus allowing to achieve a particularly high overall efficiency.

In one embodiment which may be combined with one or more of the before-addressed embodiments, said layer of substantially intrinsic a-Si:H has a thickness between 150 nm and 350 nm, more particularly of between 180 nm and 310 nm.

In one embodiment which may be combined with one or more of the before-addressed embodiments, a thickness of a layer stack starting with and including said first layer of n-doped a-Si:H and ending with and including said layer of n-doped μc-Si:H is at least 10 nm and at most 50 nm. In particular, said first layer of n-doped a-Si:H has a thickness of at least 5 nm and at most 30 nm. And in particular, said layer of n-doped μc-Si:H has a thickness of at least 5 nm and at most 30 nm.

In one embodiment which may be combined with one or more of the before-addressed embodiments, a thickness of said second layer of n-doped a-Si:H is between 10 nm and 50 nm, in particular between 20 nm and 40 nm.

In one embodiment which may be combined with one or more of the before-addressed embodiments, a thickness of said second conductive oxide layer is at most 1.8 μm, in particular between 1.4 μm and 1.7 μm. A maximum thickness of 1.8 μm has turned out to be sufficient (in conjunction with the other features of the photovoltaic cell) and allows to have an overall short deposition time.

In one embodiment which may be combined with one or more of the before-addressed embodiments, said second conductive oxide layer is at least semi-transparent. It can be substantially transparent, in particular when using a suitable back reflector.

In one embodiment which may be combined with one or more of the before-addressed embodiments, said second conductive oxide layer is n-doped, in particular by boron, more particularly by means of diborane.

In one embodiment which may be combined with one or more of the before-addressed embodiments, said second conductive oxide layer is optimized for a high electrical conductivity (perpendicularly to the layer extension), and—to a smaller extent—for a strong scattering. Providing for a strong scattering and a suitable amount of transparency allows—when using a suitable back reflector—to do with a relatively low thickness of said layer of substantially intrinsic μc-Si:H.

In one embodiment which may be combined with one or more of the before-addressed embodiments, the photovoltaic cell comprises a back reflector. Said back reflector can be, e.g., a foil applied to the photovoltaic cell, in particular to said second conductive oxide layer, and wherein the back reflector preferably is reflective and white. It is possible to use paint or color, in particular white paint or color, as a backreflector, e.g., by applying the same to said second conductive oxide layer. It is alternatively possible to use a back reflector substantially made of a metal, in particular a metal coating. Back reflectors substantially of metal function supportive for said second conductive oxide layer.

The photovoltaic converter panel according to the invention comprises at least one photovoltaic cell according to the invention.

In one embodiment of the photovoltaic converter panel, the photovoltaic converter panel comprises a multitude of photovoltaic cells according to the invention and has a surface extent of at least 2500 cm². This clearly distinguishes the photovoltaic converter panel from laboratory samples.

The invention comprises photovoltaic converter panels with features of corresponding photovoltaic cells according to the invention, and vice versa.

The advantages of the photovoltaic converter panels correspond to the advantages of corresponding photovoltaic cells and vice versa.

The method for manufacturing a photovoltaic cell or a photovoltaic converter panel comprises the steps of depositing on a transparent substrate in the following order:

b) a first conductive oxide layer;
c) a first p-i-n junction;
d) a second p-i-n junction;
e) a second conductive oxide layer;
wherein step b) comprises or substantially consists in depositing a substantially transparent ZnO layer by means of low-pressure chemical vapor deposition; and step e) comprises or substantially consists in depositing an at least partially transparent ZnO layer by means of low-pressure chemical vapor deposition; and wherein step c) comprises the following steps in the following order:
c0) depositing a layer of p-doped a-Si:H by means of PECVD in such a way that it has at its end region facing toward said second p-i-n junction a higher band gap than at its end region facing toward said first conductive oxide layer;
c4) depositing a buffer layer of a-Si:H by means of PECVD without voluntary addition of a dopant;
c5) depositing a layer of substantially intrinsic a-Si:H by means of PECVD;
c6) depositing a first layer of n-doped a-Si:H by means of PECVD; and
c7) depositing a layer of n-doped μc-Si:H by means of PECVD; and
   wherein step d) comprises the following steps in the following order:
d1) depositing a layer of p-doped μc-Si:H by means of PECVD;
d2) depositing a layer of substantially intrinsic μc-Si:H by means of PECVD; and
d3) depositing a second layer of n-doped a-Si:H deposited by means of PECVD.

This allows to mass-produce in an efficient way photovoltaic cells and photovoltaic converter panels which have a high-efficiency.

In one embodiment of the method, step c4) is as follows:
c4) depositing a buffer layer of a-Si:H by means of PECVD without voluntary addition of a dopant to PECVD reactant gases.

In one embodiment of the method which may be combined with the before-addressed embodiment, the method is a method for large-scale industrial manufacturing of photovoltaic cells and photovoltaic converter panels, respectively, in particular of photovoltaic converter panels of at least 2500 cm² surface extent.

In one embodiment which may be combined with one or more of the before-addressed embodiments of the method, in said depositing steps, deposition parameters and deposition times are chosen such that for a thickness d_{TCO} of said first conductive oxide layer applies 1 μm≦d_{TCO}≦4 μm, more particularly 1.3 μm≦d_{TCO}≦3 μm.

In one embodiment which may be combined with one or more of the before-addressed embodiments of the method, in said depositing steps, deposition parameters and deposition times are chosen such that a thickness of said layer of p-doped a-Si:H is at least 8 nm and at most 20 nm, in particular at least 9 nm and at most 17 nm.

In one embodiment which may be combined with one or more of the before-addressed embodiments of the method, in said depositing steps, deposition parameters and deposition times are chosen such that said buffer layer has a thickness of at least 2 nm and at most 15 nm, more particularly of at least 5.5 nm and at most 12 nm.

In one embodiment which may be combined with one or more of the before-addressed embodiments of the method, in said depositing steps, deposition parameters and deposition times are chosen such that said layer of substantially intrinsic a-Si:H has a thickness of at least 150 nm and at most 350 nm, more particularly of at least 180 nm and at most 310 nm.

In one embodiment which may be combined with one or more of the before-addressed embodiments of the method, in said depositing steps, deposition parameters and deposition times are chosen such that a thickness of a layer stack starting with and including said first layer of n-doped a-Si:H and ending with and including said layer of n-doped μc-Si:H is at least 10 nm and at most 50 nm.

In one embodiment which may be combined with one or more of the before-addressed embodiments of the method, in said depositing steps, deposition parameters and deposition times are chosen such that said layer of p-doped μc-Si:H has a thickness of at least 10 nm and at most 30 nm.

In one embodiment which may be combined with one or more of the before-addressed embodiments of the method, in said depositing steps, deposition parameters and deposition times are chosen such that a thickness dᵢ of said layer of substantially intrinsic μc-Si:H is at least 0.8 μm and at most 2 μm, more particularly at least 1 μm and at most 1.6 μm.

In one embodiment which may be combined with one or more of the before-addressed embodiments of the method, in said depositing steps, deposition parameters and deposition times are chosen such that said second layer of n-doped a-Si:H has a thickness of at least 10 nm and of at most 50 nm, in particular of 30 nm±10 nm.

In one embodiment which may be combined with one or more of the before-addressed embodiments of the method, in said depositing steps, deposition parameters and deposition times are chosen such that a thickness of said second conductive oxide layer is at most 1.8 μm, in particular between 1.4 μm and 1.7 μm.

In one embodiment which may be combined with one or more of the before-addressed embodiments of the method, step c0) comprises the steps of or substantially consists in the steps of
c1) depositing a first layer of p-doped a-Si:H by means of PECVD;
c2) depositing a second layer of p-doped a-Si:H by means of PECVD having a higher band gap than said first layer of p-doped a-Si:H.

As has been described before, there are other possibilities to accomplish step c0), e.g., carrying out a continuous variation of a gas during step c0), such as varying the CH₄ content of the reactant gases during the PECVD process of step c0).

In one embodiment of the method which may be combined with the before-addressed embodiment,
in step c1), deposition parameters and deposition times are chosen such that a thickness of said first layer of p-doped a-Si:H is at most 10 nm, in particular at most 7 nm, more particularly between 1 nm and 6 nm; and wherein
in step c2), deposition parameters and deposition times are chosen such that a thickness of said second layer of p-doped a-Si:H is larger than said thickness of said first layer of p-doped a-Si:H, and in particular such that said thickness of said second layer of p-doped a-Si:H is at least 5 nm and at most 16 nm.

In one embodiment which may be combined with one or more of the before-addressed embodiments of the method, the method comprises carrying out after step c0) and before step c4) the step of
c3) exposing said second layer of p-doped a-Si:H to a vapor or gas comprising water or an alcohol.

In one embodiment of the method which may be combined with the before-addressed embodiment, step c3) is carried out by dosing said water or alcohol in a vacuum chamber in which at least steps c0) and c4) were carried out without breaking the vacuum therein, in particular wherein the dosing is carried out at a pressure between 0.05 mbar to 100 mbar, and in particular at a substrate temperature between 100° C. and 350° C., and in particular dosing for less than 10 minutes, more particularly for less than 5 minutes.

In one embodiment comprising said dosing, said dosing is carried out without exposing said second layer of p-doped a-Si:H to a plasma.

It is expected that, as a result of said dosing, residual doping material present in the vacuum chamber from step c0) on internal surfaces of said reaction chamber is—at least to a large extent—transformed into stable chemical compounds unable to desorb. Accordingly, already said buffer layer and, more importantly and to a larger extent, said layer of substantially intrinsic a-Si:H have an extremely low level of dopant contamination (usually boron-contamination). Furthermore, oxygen contamination of the named two layers might be reduced by step c3), too.

Further details of the process of step c3) can be found in US 2008/0076237 A1, which therefore is hereby incorporated by reference in the present patent application.

In one embodiment which may be combined with one or more of the before-addressed embodiments of the method comprising step c3), said vapor or gas comprises water or, more particularly, substantially is water.

In one embodiment which may be combined with one or more of the before-addressed embodiments of the method comprising step c3), said vapor or gas comprises methanol.

In one embodiment which may be combined with one or more of the before-addressed embodiments of the method comprising step c3), said vapor or gas comprises isopropanol.

In one embodiment which may be combined with one or more of the before-addressed embodiments of the method comprising step c3), step c3) comprises before said exposing said second layer of p-doped a-Si:H to said vapor or gas the step of cleaning the gas inlet system (of the vacuum chamber in which the PECVD processes are carried out) from other gases by letting flow a gas through it, in particular silane. This way, the gas inlet system is cleaned from residual gases still in the gas inlet system due to former process steps.

In one embodiment which may be combined with one or more of the before-addressed embodiments of the method, the method comprises depositing said buffer layer at a growth rate smaller than a growth rate of the deposition of said layer of p-doped a-Si:H in step c0), in particular depositing said buffer layer at a growth rate of at most half of a growth rate of the deposition of said layer of p-doped a-Si:H in step c0).

In one embodiment which may be combined with one or more of the before-addressed embodiments of the method, the method comprises carrying out after step c7) and before step d1) the step of
c8) exposing said layer of n-doped μc-Si:H to an oxygen-containing plasma, in particular to a plasma containing besides oxygen also phosphorus, for forming a first oxide layer having a thickness of less than 2.5 nm, in particular less than 2 nm, more particularly between 0.1 nm and 1.5 nm.

The plasma acts as a source of oxygen radicals. The oxygen radicals interact with the surface to be treated. Using CO₂ as a feed gas for the plasma, oxygen will be released from the carbon dioxide, presumably resulting essentially in carbon monoxide and oxygen radicals. As has been mentioned before when referring to the photovoltaic cells according to the invention, it is, more generally, possible to use an oxygen-containing gas atmosphere for forming said first oxide layer; it is not necessary that the gas atmosphere is CO₂-based, and it is also not necessary that the gas atmosphere is plasma-excited. The same applies also to the second and to the third oxide layer.

Forming said first oxide layer allows to achieve an increased reproducibility and process stability. This applies in particular, if the substrate is transferred into a different vacuum chamber between step c7) and step d1), more particularly if a sample transfer between these steps comprises a breaking of the vacuum and an exposure to ambient atmosphere.

In particular, a gas mixing ratio of phosphine (PH₃) and CO₂ is between 1:1000 and 1:1, more particularly between 1:100 and 1:10.

In one embodiment which may be combined with one or more of the before-addressed embodiments of the method comprising step c8), a gas with which said plasma is fed substantially consists of CO₂ and PH₃ and the plasma discharge can be realized as an RF-, HF-, VHF- or DC-discharge, e.g., by a microwave discharge.

In one embodiment which may be combined with one or more of the before-addressed embodiments of the method comprising step c8), a gas fed to a vacuum chamber in which step c8) is carried out for feeding said plasma is fed at a rate of 0.05 to 50 standard liter/minute and per m² electrode area, more particularly at 0.1 to 5 standard liter/minute and per m² electrode area.

In one embodiment which may be combined with one or more of the before-addressed embodiments of the method comprising step c8), the plasma treatment takes place in an atmosphere of a pressure in the range between 0.01 mbar and 100 mbar, preferably between 0.1 mbar and 2 mbar.

In one embodiment which may be combined with one or more of the before-addressed embodiments of the method comprising step c8), a power density of the plasma is selected to be low, in particular between 15 and 100 mW/cm² electrode surface, more particularly between 25 and 50 mW/cm² electrode surface.

In one embodiment which may be combined with one or more of the before-addressed embodiments of the method comprising step c8), the treatment described in step c8) is tailored in such a manner that the substrate temperature remains approximately at the value it has at the end of step c7).

This way, heating-up and cooling-down cycles may be avoided.

In one embodiment which may be combined with one or more of the before-addressed embodiments of the method comprising step c8), step c8) is carried out for a duration between 2 sec and 120 sec, more particularly between 2 sec and 30 sec.

In one embodiment which may be combined with one or more of the before-addressed embodiments of the method comprising step c8), step c8) is carried out in the same vacuum chamber in which step c7) has been carried out. This helps to optimize the overall manufacturing and throughput.

In one embodiment which may be combined with one or more of the before-addressed embodiments of the method, the method comprises carrying out after step d3) and before step e) the step of
d4) creating a second oxide layer by carrying out one of the steps of
   d4′) exposing said second layer of n-doped a-Si:H to an oxygen-containing plasma, for forming said second oxide layer;
   and
   d4″) depositing said second oxide layer onto said second layer of n-doped a-Si:H using PECVD using a feed gas comprising an oxygen-containing gas species and a silicon-containing gas species;
      wherein said second oxide layer has a thickness of less than 2.5 nm, in particular less than 2 nm, more particularly between 0.1 nm and 1.5 nm.

It is possible to provide that said second oxide layer contains phosphorus. In this case, in step d4′), said plasma contains besides oxygen also phosphorus, e.g., by feeding PH₃, and in case of in step d4′), said feed gas comprises, in addition, a phosphorus-containing species such as PH₃.

With respect to this second oxide layer and step d4′), the same advantages can be achieved, and the same details and process parameters as put forward for step c8) can be used here, too; only, one has to exchange step c7) and the corresponding layer of n-doped μc-Si:H against step d3) and the corresponding second layer of n-doped a-Si:H, and step d1) against step e). Note that in step d4), both is possible, the provision of phosphorus and a phosphorus-free second oxide layer; in the latter case, a feed gas for the plasma could, e.g., be composed substantially of CO₂.

In one embodiment which may be combined with one or more of the before-addressed embodiments of the method, the method comprises carrying out after step c6) and before step c7) the step of
c65) exposing said first layer of n-doped a-Si:H to an oxygen-containing plasma, in particular to a plasma containing besides oxygen also phosphorus, for forming a third oxide layer having a thickness of less than 2.5 nm, in particular less than 2 nm, more particularly between 0.1 nm and 1.5 nm.

With respect to this third oxide layer and step c65), the same advantages can be achieved, and the same details and process parameters as put forward for step c8) can be used here, too; only, one has to exchange step c7) and the corresponding layer of n-doped μc-Si:H against step c6) and the corresponding first layer of n-doped a-Si:H, and step d1) against step c7).

The invention comprises photovoltaic cells and photovoltaic converter panels with features of corresponding methods according to the invention, and vice versa.

The advantages of the methods correspond to the advantages of corresponding devices and vice versa.

Further embodiments and advantages emerge from the dependent claims and the figures.

### BRIEF DESCRIPTION OF THE DRAWINGS

Below, the invention is described in more detail by means of examples and the included drawings. The figures show:

FIG. 1 schematically, a cross-section through a single photovoltaic cell as a prior art example;

FIG. 2 schematically, a cross-section through a photovoltaic cell as a second prior art example, namely through a tandem cell;

FIG. 3 schematically, a cross-section through a tandem photovoltaic cell.

The reference symbols used in the figures and their meaning are summarized in the list of reference symbols. The described embodiments are meant as examples and shall not confine the invention.

### DETAILED DESCRIPTION OF THE INVENTION

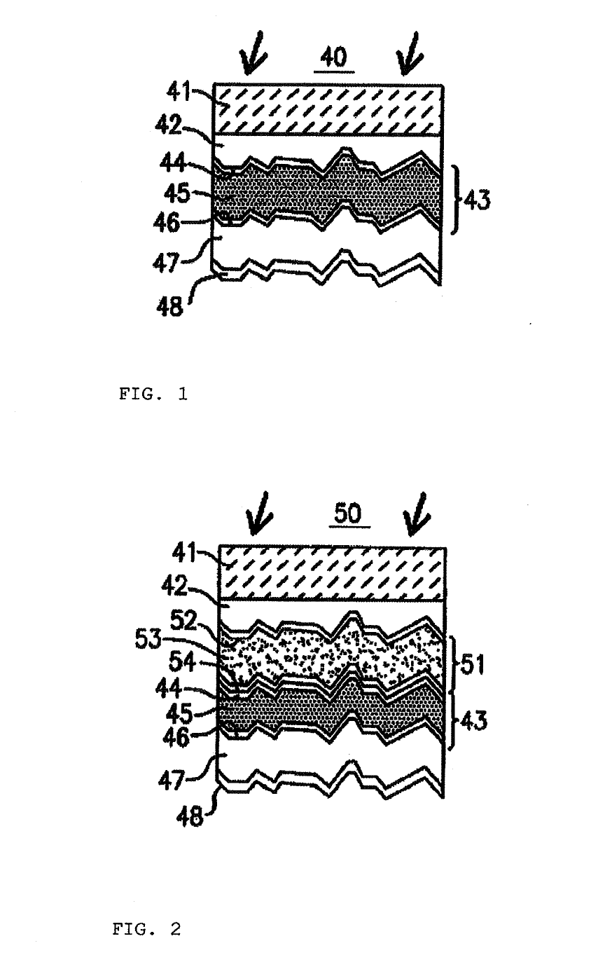

FIGS. 1 and 2 have already been described above.

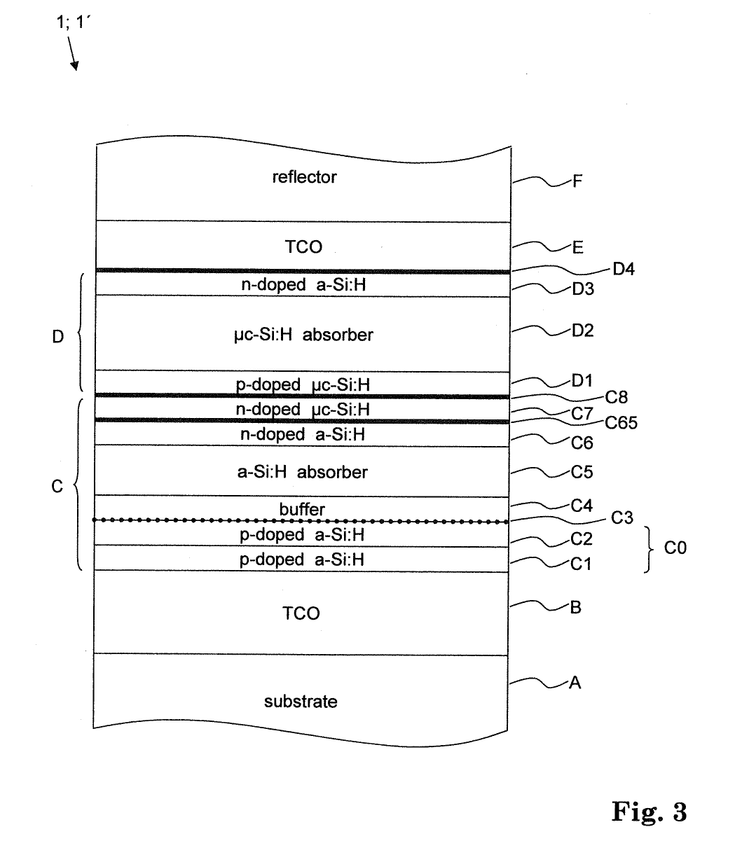

FIG. 3 shows a schematic cross-section through a tandem photovoltaic cell 1, thus at the same time representing a schematic cross-section through a detail of a corresponding photovoltaic converter panel 1′.

Further above in the description, very many details of the photovoltaic cell 1 and the photovoltaic converter panel 1′, respectively, have already been disclosed. This will not be repeated here. It is referred to the disclosure above and to the List of Reference Symbols below.

In the following, some further details and explanations will be given. Note that layers are designated using capital letters, whereas method steps are designated using lowercase letters. Layers and their corresponding manufacturing steps are generally designated alike, but are distinguishable by the use of capital letters and lowercase letters, respectively.

FIG. 3 shows, in which order the respective layers are deposited on substrate A and in which order the method steps for manufacturing the cell 1 and panel 1′, respectively, are carried out.

The described cells and panels have been manufactured using an Oerlikon Solar KAI apparatus.

For all PECVD processes, an excitation frequency of 40 MHz has been used. It would be possible to use even higher frequencies.

The dopant atoms in p-doped silicon are boron atoms. The dopant atoms in n-doped silicon are phosphorus atoms.

The dopant atoms in p-doped ZnO are phosphorus atoms. The dopant atoms in n-doped ZnO are boron atoms.

Layer C1 has a thickness of 5 nm±1 nm.

Layer C2 has a thickness of 10 nm±1 nm.

Deposition parameters (gases and gas flow rates, plasma excitation power and deposition times) for layers C1, C2, C4, C5, C6, C7 can be found in the following table:

| | SiH₄ | H₂ | TMB | CH₄ | PH₃ | Power | Time |
|---|---|---|---|---|---|---|---|
| Layer | (sccm)* | (sccm)* | (sccm)* | (sccm)* | (sccm)* | (W)** | (s) |
| C1 | 500 | 520 | 265 | 0 | 0 | 494 | 5 |
| C2 | 240 | 480 | 360 | 550 | 0 | 300 | 30 |
| C4 | 208 | 2080 | 0 | 50 | 0 | 299 | 100 |
| C5 | 520 | 520 | 0 | 0 | 0 | 330 | 775 |
| C6 | 312 | 733 | 0 | 0 | 166 | 395 | 10 |
| C7 | 41 | 4300 | 0 | 0 | 51 | 1600 | 300 |

*sccm = standard cubic centimetres per minute
**The areal power can be obtained by dividing the power by 110 × 130 cm²
(TMB = Trimethylboron)

As to layers C65, C8 and D4, the plasma treatment is carried out by exposing the workpiece (cell or panel, as far as manufactured at the respective instance) with its surface to an oxygen containing atmosphere in which a plasma discharge is generated. Thereby, there is established in the respective processing chamber an atmosphere containing a gas or gas mixture which acts as a source of oxygen radicals. The processing step is performed in the same processing chamber as the previous PECVD process. The pressure of the atmosphere for the treatment is selected in the range between 0.01 and 100 mbar, preferably between 0.1 and 2 mbar. The power density of the plasma is selected to be between 5 and 2500 mW/cm² (relative to the electrode area), preferably between 15 and 100 mW/cm². The treatment time may generally be between 2 sec. and 600 sec, preferably between 2 and 60 sec. If, as today preferred, the plasma discharge and thus the treatment is performed in a predominantly CO₂ containing atmosphere, gas is fed to the treatment chamber at a rate of 0.05 to 50 standard liter/minute and per m² electrode area, which today amounts to typically between 0.1 and 5 standard liter/minute and per m² electrode area.

As to layer D3, it has to be noted that the deposition rate of doped amorphous semiconductor material is substantially higher than the deposition rate of equally doped microcrystalline semiconductor material, and furthermore, that process stability for depositing such amorphous layers is significantly less critical than for depositing respective microcrystalline layers. And moreover, the power consumption for deposition of the addressed amorphous layers is significantly lower than for depositing corresponding microcrystalline layers at equal deposition rates. Thus, providing not a doped microcrystalline layer as layer D3, but a doped amorphous layer, as proposed in the present invention, results in a considerable improvement in large-scale industrial manufacturing of photovoltaic cells and photovoltaic converter panels, respectively.

The following parameters have been used for depositing layer D1:

| | |
|---|---|
| RF power of the plasma discharge | of the order of 0.1 W/cm² |
| per unit of substrate surface: | |
| Reactive gas: | Hydrogen, Silane and Trimethylboron |
| | as a p-dopant. |
| Total pressure: | 2.5 mbar |
| Deposition rate: | 1 Å/sec. |
| Deposition time: | about 3 min. |

During coating, the substrate had a temperature in the range of 150° C. to 220° C.

The reactive gases are optionally purified with respect to oxygen content (as well as possible today). The use of such purified gas primarily avoids already during deposition of the addressed layer D1 an oxygen contamination of the vacuum chamber.

The following parameters have been used for depositing layer D2:

| | |
|---|---|
| RF power of the plasma discharge | at least in the order of 0.1 W/cm² |
| per unit of substrate surface: | |
| Reactive gases: | Hydrogen, Silane |
| Total pressure: | 2.5 mbar |
| Deposition rate: | in the range of 5 to 6 Å/sec |

During coating, the substrate had a temperature in the range of 150° C. to 220° C.

The following parameters have been used for depositing layer D3:

| | |
|---|---|
| Rf power of the plasma discharge | at least of the order of 0.01 W/cm² |
| per unit of substrate surface: | |
| Reactive gas: | Hydrogen, Silane, Phosphine |
| | as n-dopant. |
| Total pressure: | 0.5 mbar |
| Deposition rate: | in the range of 2-3 Å/sec |

During coating, the substrate had a temperature in the range of 150° C. to 220° C.

The following results have been obtained:

For photovoltaic converter panels of 1.4 m² containing 99 photovoltaic cells, the following average results (average over 300 panels), and the following best results have been obtained in series production under series production conditions:

| | average of 300 panels/best panel |
|---|---|
| initial V_{OC}: | 132.1 V/133.2 V |
| initial I_{SC}: 1.5 A | 1.533 A/1.567 A |
| initial power P: 128 W | 133.2 W/139.8 W |
| fill factor: | 65.7%/67% |

(V_{OC} designates the open circuit voltage and I_{SC} designates the short circuit current.)

The proposed photovoltaic cell 1 and photovoltaic converter panel 1′ and the corresponding manufacturing method allow to achieve excellent efficiencies in industrial-scale manufacture.

### LIST OF REFERENCE SYMBOLS

1 photovoltaic cell
1′ photovoltaic converter panel
A substrate
B first conductive oxide layer
C first p-i-n junction
C0 layer of p-doped a-Si:H
C1 first layer of p-doped a-Si:H
C2 second layer of p-doped a-Si:H
C3 indication of effect of step c3)
C4 buffer layer
C5 layer of substantially intrinsic a-Si:H
C6 first layer of n-doped a-Si:H
C65 third oxide layer
C7 layer of n-doped μc-Si:H
C8 first oxide layer
D second p-i-n junction
D1 layer of p-doped μc-Si:H
D2 layer of substantially intrinsic μc-Si:H
D3 second layer of n-doped a-Si:H
D4 second oxide layer
E second conductive oxide layer
F back reflector

1. A photovoltaic cell comprising, deposited on a transparent substrate in the following order,
a first conductive oxide layer;
a first p-i-n junction;
a second p-i-n junction;
a second conductive oxide layer;
wherein
said first conductive oxide layer is substantially transparent and comprises a low-pressure chemical vapor deposited ZnO layer; and
said second conductive oxide layer comprises an at least partially transparent low-pressure chemical vapor deposited ZnO layer; and
wherein said first p-i-n junction comprises in the following order
a layer of p-doped a-Si:H deposited using PECVD and having at its end region facing toward said second p-i-n junction a higher band gap than at its end region facing toward said first conductive oxide layer;
a buffer layer of a-Si:H deposited using PECVD without voluntary addition of a dopant;
a layer of substantially intrinsic a-Si:H deposited using PECVD;
a first layer of n-doped a-Si:H deposited using PECVD; and
a layer of n-doped μc-Si:H deposited using PECVD; and
wherein said second p-i-n junction comprises in the following order a layer of p-doped μc-Si:H deposited using PECVD;
a layer of substantially intrinsic μc-Si:H deposited using PECVD; and
a second layer of n-doped a-Si:H deposited using PECVD.

2. The photovoltaic cell according to claim 1, wherein for a thickness d_{TCO} of said first conductive oxide layer applies 1 μm≦d_{TCO}≦4 μm, more particularly 1.3 μm≦d_{TCO}≦3 μm, and wherein for said thickness d_{TCO} and for a thickness dᵢ of said layer of substantially intrinsic μc-Si:H applies 1.25≦(d_{TCO}/μm)·(dᵢ/μm−0.4)≦2, more particularly 1.35≦(d_{TCO}/μm)·(dᵢ/μm−0.4)≦1.85.

3. The photovoltaic cell according to claim 1 or claim 2, wherein said bandgap of said layer of p-doped a-Si:H at said end region facing toward said second p-i-n junction is higher than said bandgap of said layer of p-doped a-Si:H at said end region facing toward said first conductive oxide layer by at least 0.15 eV, more particularly by at least 0.2 eV and at most 0.5 eV.

4. The photovoltaic cell according to any of the preceding claims, wherein said layer of p-doped a-Si:H comprises
a first layer of p-doped a-Si:H deposited using PECVD; and
a second layer of p-doped a-Si:H deposited using PECVD and having a higher band gap than said first layer of p-doped a-Si:H.

5. The photovoltaic cell according to claim 4, wherein a thickness of said first layer of p-doped a-Si:H is at most 10 nm, in particular at most 7 nm, and wherein a thickness of said second layer of p-doped a-Si:H is at least 5 nm and at most 16 nm, and wherein said thickness of said second layer of p-doped a-Si:H is larger than said thickness of said first layer of p-doped a-Si:H.

6. The photovoltaic cell according to one of the preceding claims, comprising in the before-described sequence of layers immediately before said layer of p-doped μc-Si:H a first oxide layer having a thickness of less than 2.5 nm, in particular less than 2 nm, more particularly between 0.1 nm and 1.5 nm.

7. The photovoltaic cell according to one of the preceding claims, comprising in the before-described sequence of layers immediately before said second conductive oxide layer a second oxide layer having a thickness of less than 2.5 nm, in particular less than 2 nm, more particularly between 0.1 nm and 1.5 nm.

8. The photovoltaic cell according to one of the preceding claims, comprising in the before-described sequence of layers immediately before said layer of n-doped μc-Si:H a third oxide layer having a thickness of less than 2.5 nm, in particular less than 2 nm, more particularly between 0.1 nm and 1.5 nm.

9. The photovoltaic cell according to one of the preceding claims, wherein said buffer layer has a thickness of at least 2 nm and at most 15 nm, more particularly of at least 5 nm and at most 12 nm.

10. The photovoltaic cell according to one of the preceding claims, wherein said buffer layer is deposited using PECVD at a growth rate smaller than a growth rate of the deposition of said layer of p-doped a-Si:H, and in particular is deposited using PECVD at a growth rate of at most half of a growth rate of the deposition of said layer of p-doped a-Si:H.

11. The photovoltaic cell according to one of the preceding claims, wherein a thickness dᵢ of said layer of substantially intrinsic μc-Si:H is at least 0.8 μm and at most 2 μm, more particularly at least 1 μm and at most 1.6 μm.

12. The photovoltaic cell according to one of the preceding claims, wherein a thickness dᵢ of said layer of substantially intrinsic μc-Si:H is at least 4 times and at most 8 times as large as a thickness of said layer of substantially intrinsic a-Si:H.

13. The photovoltaic cell according to one of the preceding claims, wherein a thickness of a layer stack starting with and including said first layer of n-doped a-Si:H and ending with and including said layer of n-doped μc-Si:H is at least 10 nm and at most 50 nm.

14. The photovoltaic cell according to one of the preceding claims, wherein a thickness of said second conductive oxide layer is at most 1.8 μm, in particular between 1.4 μm and 1.7 μm.

15. A photovoltaic converter panel comprising at least one photovoltaic cell according to one of the preceding claims.

16. The photovoltaic converter panel according to claim 15, comprising a multitude of photovoltaic cells according to one claims 1 to 14 and having a surface extent of at least 2500 cm².

17. Method for manufacturing a photovoltaic cell or a photovoltaic converter panel, comprising the steps of depositing on a transparent substrate in the following order:
b) a first conductive oxide layer;
c) a first p-i-n junction;
d) a second p-i-n junction;
e) a second conductive oxide layer;
wherein step b) comprises depositing a substantially transparent ZnO layer by means of low-pressure chemical vapor deposition; and
step e) comprises depositing an at least partially transparent ZnO layer by means of low-pressure chemical vapor deposition; and
wherein step c) comprises the following steps in the following order:
c0) depositing a layer of p-doped a-Si:H by means of PECVD in such a way that it has at its end region facing toward said second p-i-n junction a higher band gap than at its end region facing toward said first conductive oxide layer;
c4) depositing a buffer layer of a-Si:H by means of PECVD without voluntary addition of a dopant;
c5) depositing a layer of substantially intrinsic a-Si:H by means of PECVD;
c6) depositing a first layer of n-doped a-Si:H by means of PECVD; and
c7) depositing a layer of n-doped μc-Si:H by means of PECVD; and
wherein step d) comprises the following steps in the following order:
d1) depositing a layer of p-doped μc-Si:H by means of PECVD;
d2) depositing a layer of substantially intrinsic μc-Si:H by means of PECVD; and
d3) depositing a second layer of n-doped a-Si:H deposited by means of PECVD.

18. The method according to claim 17, characterized in being a method for large-scale industrial manufacturing of photovoltaic cells and photovoltaic converter panels, respectively, in particular of photovoltaic converter panels of at least 2500 cm² surface extent.

19. The method according to claim 17 or claim 18, wherein in said depositing steps, deposition parameters and deposition times are chosen such that for a thickness d_{TCO} of said first conductive oxide layer applies 1 μm≦d_{TCO}≦4 μm, more particularly 1.3 μm≦d_{TCO}≦3 μm;
a thickness of said layer of p-doped a-Si:H is at least 8 nm and at most 20 nm, in particular at least 9 nm and at most 17 nm;
said buffer layer has a thickness of at least 2 nm and at most 15 nm, more particularly of at least 5.5 nm and at most 12 nm;
said layer of substantially intrinsic a-Si:H has a thickness of at least 150 nm and at most 350 nm, more particularly of at least 180 nm and at most 310 nm;
a thickness of a layer stack starting with and including said first layer of n-doped a-Si:H and ending with and including said layer of n-doped μc-Si:H is at least 10 nm and at most 50 nm;
said layer of p-doped μc-Si:H has a thickness of at least 10 nm and at most 30 nm;
a thickness dᵢ of said layer of substantially intrinsic μc-Si:H is at least 0.8 μm and at most 2 μm, more particularly at least 1 μm and at most 1.6 μm;
said second layer of n-doped a-Si:H has a thickness of at least 10 nm and of at most 50 nm, in particular of 30 nm±10 nm;
a thickness of said second conductive oxide layer is at most 1.8 μm, in particular between 1.4 μm and 1.7 μm.

20. The method according to one of claims 17 to 19 wherein step c0) comprises the steps of
c1) depositing a first layer of p-doped a-Si:H by means of PECVD;
c2) depositing a second layer of p-doped a-Si:H by means of PECVD having a higher band gap than said first layer of p-doped a-Si:H.

21. The method according to claim 20, wherein
in step c1), deposition parameters and deposition times are chosen such that a thickness of said first layer of p-doped a-Si:H is at most 10 nm, in particular at most 7 nm; and wherein
in step c2), deposition parameters and deposition times are chosen such that a thickness of said second layer of p-doped a-Si:H is larger than said thickness of said first layer of p-doped a-Si:H, and in particular such that said thickness of said second layer of p-doped a-Si:H is at least 5 nm and at most 16 nm.

22. The method according to one of claims 17 to 21, comprising carrying out after step c0) and before step c4) the step of
c3) exposing said second layer of p-doped a-Si:H to a vapor or gas comprising water or an alcohol.

23. The method according to one of claims 17 to 22, comprising depositing said buffer layer at a growth rate smaller than a growth rate of the deposition of said layer of p-doped a-Si:H in step c0), in particular depositing said buffer layer at a growth rate of at most half of a growth rate of the deposition of said layer of p-doped a-Si:H in step c0).

24. The method according to one of claims 17 to 23, comprising carrying out after step c7) and before step d1) the step of
c8) exposing said layer of n-doped μc-Si:H to an oxygen-containing plasma, in particular to a plasma containing besides oxygen also phosphorus, for forming a first oxide layer having a thickness of less than 2.5 nm, in particular less than 2 nm, more particularly between 0.1 nm and 1.5 nm.

25. The method according to one of claims 17 to 24, comprising carrying out after step d3) and before step e) the step of
d4) creating a second oxide layer by carrying out one of the steps of
d4′) exposing said second layer of n-doped a-Si:H to an oxygen-containing plasma, for forming said second oxide layer;
and
d4″) depositing said second oxide layer onto said second layer of n-doped a-Si:H using PECVD using a feed gas comprising an oxygen-containing gas species and a silicon-containing gas species;
wherein said second oxide layer has a thickness of less than 2.5 nm, in particular less than 2 nm, more particularly between 0.1 nm and 1.5 nm.

26. The method according to one of claims 17 to 25, comprising carrying out after step c6) and before step c7) the step of
c65) exposing said first layer of n-doped a-Si:H to an oxygen-containing plasma, in particular to a plasma containing besides oxygen also phosphorus, for forming a third oxide layer having a thickness of less than 2.5 nm, in particular less than 2 nm, more particularly between 0.1 nm and 1.5 nm.
